(19) United States
(12) Patent Application Publication
(10) Pub. No.: US 2025/0112197 A1
(43) Pub. Date: Apr. 3, 2025

(54) WIREBOND MULTICHIP PACKAGE

(71) Applicant: MEDIATEK INC., Hsinchu City (TW)

(72) Inventors: Yu-Liang Hsiao, Hsinchu City (TW); Ming-Hsien Chou, Hsinchu City (TW)

(73) Assignee: MEDIATEK INC., Hsinchu City (TW)

(21) Appl. No.: 18/892,576

(22) Filed: Sep. 23, 2024

Related U.S. Application Data
(60) Provisional application No. 63/585,992, filed on Sep. 28, 2023.

(51) Int. Cl. H01L 23/00; H01L 23/31; H01L 23/538; H01L 25/18; H10B 80/00

(52) U.S. Cl. CPC H01L 24/48; H01L 24/49; H01L 25/18; H01L 23/3107; H01L 23/538; H01L 2224/48137; H01L 2224/48145; H01L 2224/48227; H01L 2224/49109; H10B 80/00

(57) ABSTRACT

A semiconductor package includes a carrier substrate comprising a first surface and a second surface opposite to the first surface. A first electronic component and a second electronic component are mounted on the first surface of the carrier substrate in a side-by-side manner. The first electronic component is provided with first data (DQ) pads along a first side directly facing the second electronic component. The second electronic component is provided with second data (DQ) pads along a second side in proximity to the first electronic component. The first DQ pads are directly connects to the second DQ pads through first bond wires.

### CROSS REFERENCE TO RELATED APPLICATIONS

This application claims the benefit of U.S. Provisional Application No. 63/585,992, filed on Sep. 28, 2023. The content of the application is incorporated herein by reference.

### BACKGROUND

The present invention relates to the field of semiconductor packaging. More specifically, the present invention relates to a wirebond multichip package with reduced package size.

In a manufacturing process which involves sealing a plurality of semiconductor chips to form a multichip package, an electrical connection between the semiconductor chips is established, for example, by wire bonding. Wire bonding is widely used and cost-effective interconnect solution for multi-chip modules and memory device packaging. The dominance of wire bonding is maintained not only due its exceptional flexibility and low cost, but also due to new generations of smart processes that have reduced optimization time, improved reliability and ensured higher yield.

Typically, a wirebond multichip package includes a SoC die and a known-good-die (KGD) memory die mounted on an upper surface of a carrier substrate in a side-by-side fashion. The communication between the SoC die and the KGD memory die is established through substrate bonding fingers and routing in consideration of the flexibility to accommodate KGD memory dies from different sources and to implement KGD memory die placement for various DDR phy orientation and DDR signal pad sequence. However, the conventional package bonding and layout methodology becomes an obstacle to the shrinkage of the package size.

### SUMMARY

One object of the present invention is to provide an improved semiconductor package, which can improve the shortcomings or shortcomings of the prior art.

One aspect of the invention provides a semiconductor package including a carrier substrate comprising a first surface and a second surface opposite to the first surface. A first electronic component and a second electronic component are mounted on the first surface of the carrier substrate in a side-by-side manner. The first electronic component is provided with a plurality of first data (DQ) pads along a first side directly facing the second electronic component. The second electronic component is provided with a plurality of second data (DQ) pads along a second side in proximity to the first electronic component. A plurality of first bond wires directly connects the plurality of first DQ pads to the plurality of second DQ pads.

According to some embodiments, the first electronic component is further provided with a plurality of first command/address (CA) pads along the first side directly facing the second electronic component, and the second electronic component is further provided with a plurality of second command/address (CA) pads along the second side directly facing the first electronic component, wherein the plurality of first CA pads is directly and electrically connected to the second CA pads through a plurality of second bond wires.

According to some embodiments, the first electronic component is further provided with a plurality of first power/ground pads in an elongated sector in front of the plurality of first DQ pads and the plurality of first CA pads along the first side.

According to some embodiments, the plurality of first power/ground pads is directly and electrically connected to a plurality of first gold fingers on the first surface of the carrier substrate through a plurality of third bond wires.

According to some embodiments, the second electronic component is further provided with a plurality of second power/ground pads between the second DQ pads and the first CA pads.

According to some embodiments, the plurality of second power/ground pads is directly and electrically connected to a plurality of second gold fingers on the first surface of the carrier substrate through a plurality of fourth bond wires.

According to some embodiments, the semiconductor package further includes a molding compound encapsulating the first electronic component, the second electronic component, the plurality of first bond wires, the plurality of second bond wires, the plurality of third bond wires, and the plurality of fourth bond wires.

According to some embodiments, the semiconductor package further includes a plurality of connecting elements on the second surface of the carrier substrate.

According to some embodiments, the first electronic component is a System on Chip (SoC).

According to some embodiments, the second electronic component is a memory chip.

Another aspect of the invention provides a semiconductor package including a carrier substrate comprising a first surface and a second surface opposite to the first surface. A first electronic component and a second electronic component are mounted on the first surface of the carrier substrate in a side-by-side manner. The second electronic component includes at least a lower DRAM die and an upper DRAM die stacked on the lower DRAM die in a stepwise manner. The first electronic component is provided with a plurality of high-speed signal pads along a first side directly facing the second electronic component. The plurality of high-speed signal pads includes a group of first data (DQ) pads arranged in a first sector adjacent to the first side, and a group of second data (DQ) pads arranged in a second sector adjacent to the first sector. The lower DRAM die is provided with a plurality of third data (DQ) pads along a second side in proximity to the first electronic component. The upper DRAM die is provided with a plurality of fourth data (DQ) pads along a third side in proximity to the first electronic component.

A plurality of first bond wires directly connects the group of first DQ pads in the first sector of the first electronic component to the plurality of third DQ pads of the lower DRAM die. A plurality of second bond wires directly connects the group of second DQ pads in the second sector of the first electronic component to the plurality of fourth DQ pads of the upper DRAM die.

According to some embodiments, the first electronic component is further provided with a plurality of first command/address (CA) pads within a side sector that is juxtaposed with the first sector and the second sector along the first side directly facing the second electronic component, and the lower DRAM die is further provided with a plurality of second command/address (CA) pads along the second side directly facing the first electronic component, wherein the plurality of first CA pads is directly and electrically connected to the second CA pads through a plurality of third bond wires.

According to some embodiments, the first electronic component is further provided with a plurality of first power/ground pads in an elongated sector in front of the side sector and the first sector along the first side.

According to some embodiments, the plurality of first power/ground pads is directly and electrically connected to a plurality of first gold fingers on the first surface of the carrier substrate through a plurality of fourth bond wires.

According to some embodiments, the second electronic component is further provided with a plurality of second power/ground pads between the third DQ pads and the first CA pads.

According to some embodiments, the plurality of second power/ground pads is directly and electrically connected to a plurality of second gold fingers on the first surface of the carrier substrate through a plurality of fifth bond wires.

According to some embodiments, the semiconductor package further includes a molding compound encapsulating the first electronic component, the second electronic component, the plurality of first bond wires, the plurality of second bond wires, the plurality of third bond wires, the plurality of fourth bond wires, and the plurality of fifth bond wires.

According to some embodiments, the semiconductor package further includes a plurality of connecting elements on the second surface of the carrier substrate.

According to some embodiments, the first electronic component is a System on Chip (SoC).

According to some embodiments, the side sector is contiguous with the first sector and the second sector.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is a schematic top view of a semiconductor package according to an embodiment of the invention; and

FIG. 2 is a schematic cross-sectional view taken along line I-I′ in FIG. 1.

### DETAILED DESCRIPTION

In the following detailed description of embodiments of the invention, reference is made to the accompanying drawings, which form a part hereof, and in which is shown by way of illustration specific preferred embodiments in which the disclosure may be practiced.

These embodiments are described in sufficient detail to enable those skilled in the art to practice them, and it is to be understood that other embodiments may be utilized and that mechanical, structural, and procedural changes may be made without departing from the spirit and scope of the present disclosure. The following detailed description is, therefore, not to be taken in a limiting sense, and the scope of embodiments of the present invention is defined only by the appended claims.

It will be understood that, although the terms first, second, third, primary, secondary, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first or primary element, component, region, layer or section discussed below could be termed a second or secondary element, component, region, layer or section without departing from the teachings of the present inventive concept.

Spatially relative terms, such as “beneath”, “below”, “lower”, “under”, “above,” “upper,” “over” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” or “over” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items, and may be abbreviated as “/”.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

Hereinafter, the term “multichip package” or “MCP” refers to a plurality of integrated circuit (IC) chips or dies with different functions that are encapsulated in a single package. The term “wirebond multichip package” or “WBMCP” refers to packaging a plurality of chips together, and at least one of the chips is interconnected by wire bonding. The term “system on chip” or “SoC” refers to an integrated circuit that integrates various components of a computer or other electronic system into a single chip. The term “kgd” or “KGD” refers to a known good die.

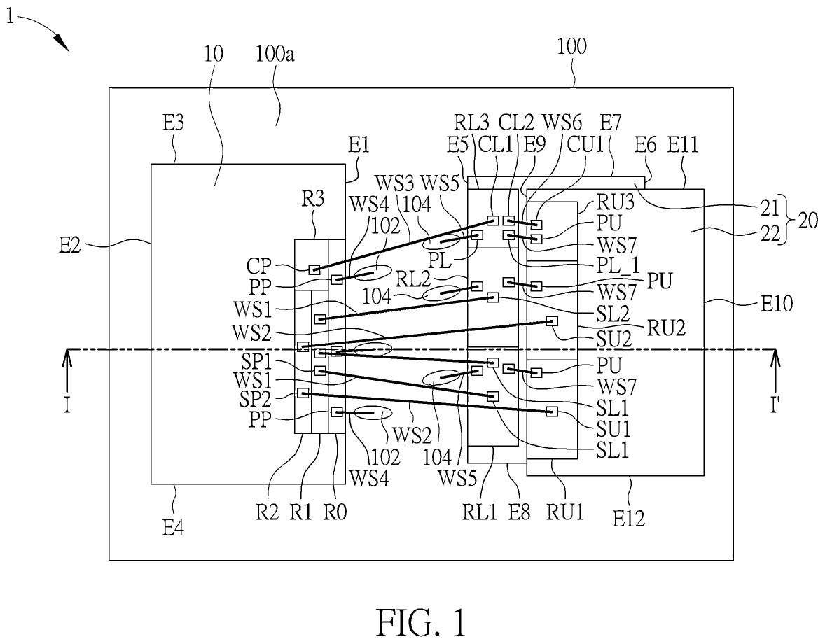

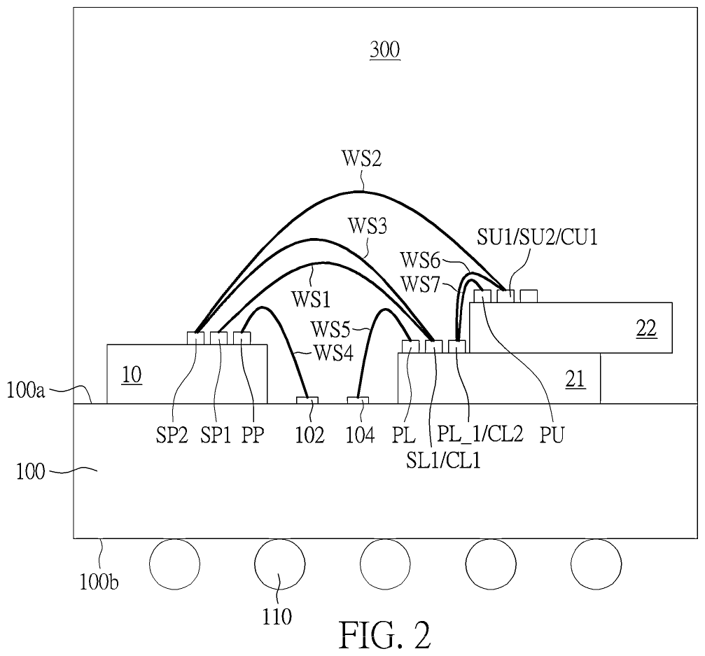

Please refer to FIG. 1 and FIG. 2, wherein FIG. 1 is a schematic top view of a semiconductor package according to an embodiment of the invention, and FIG. 2 is a schematic cross-sectional view taken along line I-I′ in FIG. 1. As shown in FIG. 1 and FIG. 2, the semiconductor package 1 includes a carrier substrate 100 having a first surface 100a and a second surface 100b opposite to the first surface 100a. According to an embodiment of the invention, for example, the semiconductor package 1 may be a wirebond multichip package, but is not limited thereto. According to an embodiment of the invention, a first electronic component 10 and a second electronic component 20 may be mounted on the first surface 100a of the carrier substrate 100 in a side-by-side manner. According to an embodiment of the invention, for example, the first electronic component 10 and the second electronic component 20 may be secured on the first surface 100a of the carrier substrate 100 with any suitable methods known in the art, for example, by using an adhesive layer.

According to an embodiment of the invention, a plurality of connecting elements 110, for example, ball grid array (BGA) solder balls, are provided on the second surface 100b of the carrier substrate 10. The semiconductor package 1 may be attached to a printed circuit board (PCB) or a motherboard (not shown) through the plurality of connecting elements 110. According to an embodiment of the invention, for example, the carrier substrate 100 may be a packaging substrate.

According to an embodiment of the invention, for example, the carrier substrate 100 may be an organic packaging substrate, including metal wires and resin, such as BT (BT: abbreviation of bismalemide triazene) epoxy resin. However, it is to be understood that other materials may be used to form the carrier substrate 100, for example, ceramic or plastic. For the sake of simplicity, the detailed internal routing of the carrier substrate 100 is not shown in FIG. 2. Only gold fingers 102, 104 are shown in FIG. 2 for illustration purposes.

According to an embodiment of the invention, for example, the first electronic component 10 may be a system on chip (SoC), and the second electronic component 20 may be a memory chip, such as a dynamic random access memory (DRAM) package including, but not limited to, more than one DRAM chip (or DRAM kdg), for example, double data rate 3 (DDR3) dies or double data rate 4 (DDR4) dies, etc. For example, the second electronic component 20 may include at least two stacked DRAM dies 21 and 22. According to an embodiment of the invention, the DRAM dies may be stacked in a stepwise manner.

According to an embodiment of the invention, the first electronic component 10 and the second electronic component 20 are mounted on the first surface 100a of the carrier substrate 100 in a side-by-side manner, and the first electronic component 10 is disposed in close proximity to the second electronic component 20, thereby reducing the overall package size.

According to an embodiment of the present invention, for example, the first electronic component 10 includes four sides E1-E4. According to an embodiment of the present invention, for example, the DRAM die 21 includes four sides E5-E8. According to an embodiment of the present invention, for example, the DRAM die 22 includes four sides E9-E12. The side E1 of the first electronic component 10 directly faces the side E5 of the DRAM die 21 and the side E9 of the DRAM die 22. According to an embodiment of the present invention, the side E1 is in parallel with the sides E2, E5, E6, E9, and E10. According to an embodiment of the present invention, the side E10 overhangs the side E6 because the DRAM die 22 stacks over the DRAM die 21 in a stepwise manner.

According to an embodiment of the present invention, for example, the first electronic component 10 comprises a plurality of high-speed signal pads SP disposed along the side E₁ that directly faces the second electronic component 20. For example, the high-speed signal pads SP may be data (DQ) pads for transmitting high-speed and/or high-frequency data signals between the first electronic component 10 and the second electronic component 20, for example, 4266 Mbps or higher data transmission rate, but not limited thereto. According to an embodiment of the present invention, for example, the high-speed signal pads SP may be divided into two groups of 16-bit DQ pads SP1 and SP2, which are arranged within two parallel sectors R1 and R2, respectively. According to an embodiment of the present invention, each of the two parallel sectors R1 and R2 may accommodate at least a row of about 20-30 DQ pads, for example, 25 DQ pads.

According to an embodiment of the present invention, for example, the first electronic component 10 further comprises a plurality of signal pads CP for transmitting command/address (CA) signals disposed along the side E1 that directly faces the second electronic component 20. According to an embodiment of the present invention, for example, the plurality of signal pads CP may be disposed within a side sector R3 that is juxtaposed with the sectors R1 and R2 along the side E1. According to an embodiment of the present invention, for example, the side sector R3 may be contiguous with the sectors R1 and R2.

According to an embodiment of the present invention, for example, the first electronic component 10 further comprises a plurality of power/ground pads PP disposed within an elongated sector R0 extending along the side E1 in front of the sector R1 and the sector R3. According to an embodiment of the present invention, for example, the elongated sector R0 may be contiguous with the sector R1 and the sector R3. According to an embodiment of the present invention, for example, the sector R1 is sandwiched by the sector R2 and the elongated sector R0. Although not shown in the figures, it is understood that the first electronic component 10 may further comprise input/output (I/O) pads for transmitting power or ground signals along the other three sides E2-E4. It is understood that the above-described pads configuration may be implemented through a re-distribution layer (RDL) structure, but is not limited thereto.

According to an embodiment of the present invention, for example, the DRAM die 21 may comprise three sectors RL1, RL2, and RL3, which are contiguous to one another, disposed along the side E5 that confronts the side E1 of the first electronic component 10. According to an embodiment of the present invention, for example, the sector RL1 accommodates a plurality of 8-bit DQ pads SL1, the sector RL2 accommodates a plurality of 8-bit DQ pads SL2, and the sector RL3 accommodates a plurality of signal pads CL1 for transmitting command/address (CA) signals. According to an embodiment of the present invention, likewise, the DRAM die 22 may comprise three contiguous sectors RU1, RU2, and RU3 disposed along the side E9. According to an embodiment of the present invention, for example, the sector RU1 accommodates a plurality of 8-bit DQ pads SU1, the sector RU2 accommodates a plurality of 8-bit DQ pads SU2, and the sector RU3 accommodates a plurality of signal pads CU1 for transmitting command/address (CA) signals.

According to an embodiment of the present invention, for example, multiple power/ground pads PL may be disposed within the three contiguous sectors RL1, RL2, and RL3, respectively. According to an embodiment of the present invention, for example, multiple power/ground pads PU may be disposed within the three contiguous sectors RU1, RU2, and RU3, respectively.

According to an embodiment of the present invention, for example, the DQ pads SP1 in the sector R1 of the first electronic component 10 may be electrically connected to the DQ pads SL1 in the sector RL1 and the DQ pads SL2 in the sector RL2 of the DRAM die 21 directly through the bond wires WS1, respectively. According to an embodiment of the present invention, for example, the DQ pads SP2 in the sector R2 of the first electronic component 10 may be electrically connected to the DQ pads SU1 in the sector RU1 and the DQ pads SU2 in the sector RU2 of the DRAM die 22 directly through the bond wires WS2, respectively. According to an embodiment of the present invention, for example, the bond wires WS1 and the bond wires WS2 may have different loop heights. According to an embodiment of the present invention, for example, the bond wires WS1 have a loop height that is smaller than a loop height of the bond wires WS2.

According to an embodiment of the present invention, for example, the signal pads CP in the sector R3 of the first electronic component 10 may be electrically connected to the signal pads CL1 in the sector RL3 of the DRAM die 21 directly through the bond wires WS3, respectively. According to an embodiment of the present invention, for example, the signal pads CU1 in the sector RU3 of the DRAM die 22 may be electrically connected to the signal pads CL2 in the sector RL3 of the DRAM die 21 directly through the bond wires WS6, respectively.

According to an embodiment of the present invention, for example, the power/ground pads PP in the elongated sector R0 of the first electronic component 10 may be electrically connected to the gold fingers 102 on the first surface 100a of the carrier substrate 100 directly through the bond wires WS4, respectively. According to an embodiment of the present invention, for example, the power/ground pads PL in the sectors RL1, RL2, and RL3 of the DRAM die 21 may be electrically connected to the gold fingers 104 on the first surface 100a of the carrier substrate 100 directly through the bond wires WS5, respectively. According to an embodiment of the present invention, for example, the power/ground pads PU in the sectors RU1, RU2, and RU3 of the DRAM die 22 may be electrically connected to the power/ground pads PL_1 in the sectors RL1, RL2, and RL3 of the DRAM die 21 directly through the bond wires WS7, respectively.

According to an embodiment of the present invention, for example, the first electronic component 10, the second electronic component 20, and the bond wires WS1-WS7 are encapsulated by a molding compound 300. According to an embodiment of the present invention, for example, the molding compound 300 may comprise polymers or resins, but is not limited thereto. The molding compound 300 also covers the first surface 100a of the carrier substrate 100.

It is advantageous to use the present invention because the DQ pads SP1 and SP2 of the first electronic component 10 are directly wire-bonded to the respective DQ pads SL1, SL2, SU1, and SU2 of the DRAM die 21 and DRAM die 22 without passing through the DDR routing of the carrier substrate 100. Therefore, the package size can be reduced.

Further, the high-speed signal pads SP of the first electronic component 10 may be divided into two groups of 16-bit DQ pads SP1 and SP2, which are arranged within the front sector R1 and the rear sector R2, respectively. By providing such configuration, the wire bonding crossing issues may be avoided.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor package, comprising:
a carrier substrate comprising a first surface and a second surface opposite to the first surface;
a first electronic component and a second electronic component mounted on the first surface of the carrier substrate in a side-by-side manner, wherein the first electronic component is provided with a plurality of first data (DQ) pads along a first side directly facing the second electronic component, wherein the second electronic component is provided with a plurality of second data (DQ) pads along a second side in proximity to the first electronic component; and
a plurality of first bond wires directly connecting the plurality of first DQ pads to the plurality of second DQ pads.

2. The semiconductor package according to claim 1, wherein the first electronic component is further provided with a plurality of first command/address (CA) pads along the first side directly facing the second electronic component, and the second electronic component is further provided with a plurality of second command/address (CA) pads along the second side directly facing the first electronic component, wherein the plurality of first CA pads is directly and electrically connected to the second CA pads through a plurality of second bond wires.

3. The semiconductor package according to claim 2, wherein the first electronic component is further provided with a plurality of first power/ground pads in an elongated sector in front of the plurality of first DQ pads and the plurality of first CA pads along the first side.

4. The semiconductor package according to claim 3, wherein the plurality of first power/ground pads is directly and electrically connected to a plurality of first gold fingers on the first surface of the carrier substrate through a plurality of third bond wires.

5. The semiconductor package according to claim 4, wherein the second electronic component is further provided with a plurality of second power/ground pads between the second DQ pads and the first CA pads.

6. The semiconductor package according to claim 5, wherein the plurality of second power/ground pads is directly and electrically connected to a plurality of second gold fingers on the first surface of the carrier substrate through a plurality of fourth bond wires.

7. The semiconductor package according to claim 6 further comprising:
a molding compound encapsulating the first electronic component, the second electronic component, the plurality of first bond wires, the plurality of second bond wires, the plurality of third bond wires, and the plurality of fourth bond wires.

8. The semiconductor package according to claim 1 further comprising:
a plurality of connecting elements on the second surface of the carrier substrate.

9. The semiconductor package according to claim 1, wherein the first electronic component is a System on Chip (SoC).

10. The semiconductor package according to claim 1, wherein the second electronic component is a memory chip.

11. A semiconductor package, comprising:
a carrier substrate comprising a first surface and a second surface opposite to the first surface;
a first electronic component and a second electronic component mounted on the first surface of the carrier substrate in a side-by-side manner, wherein the second electronic component comprises at least a lower DRAM die and an upper DRAM die stacked on the lower DRAM die in a stepwise manner, wherein the first electronic component is provided with a plurality of high-speed signal pads along a first side directly facing the second electronic component, wherein the plurality of high-speed signal pads comprises a group of first data (DQ) pads arranged in a first sector adjacent to the first side, and a group of second data (DQ) pads arranged in a second sector adjacent to the first sector, wherein the lower DRAM die is provided with a plurality of third data (DQ) pads along a second side in proximity to the first electronic component, and the upper DRAM die is provided with a plurality of fourth data (DQ) pads along a third side in proximity to the first electronic component;
a plurality of first bond wires directly connecting the group of first DQ pads in the first sector of the first electronic component to the plurality of third DQ pads of the lower DRAM die; and
a plurality of second bond wires directly connecting the group of second DQ pads in the second sector of the first electronic component to the plurality of fourth DQ pads of the upper DRAM die.

12. The semiconductor package according to claim 11, wherein the first electronic component is further provided with a plurality of first command/address (CA) pads within a side sector that is juxtaposed with the first sector and the second sector along the first side directly facing the second electronic component, and the lower DRAM die is further provided with a plurality of second command/address (CA) pads along the second side directly facing the first electronic component, wherein the plurality of first CA pads is directly and electrically connected to the second CA pads through a plurality of third bond wires.

13. The semiconductor package according to claim 12, wherein the first electronic component is further provided with a plurality of first power/ground pads in an elongated sector in front of the side sector and the first sector along the first side.

14. The semiconductor package according to claim 13, wherein the plurality of first power/ground pads is directly and electrically connected to a plurality of first gold fingers on the first surface of the carrier substrate through a plurality of fourth bond wires.

15. The semiconductor package according to claim 14, wherein the second electronic component is further provided with a plurality of second power/ground pads between the third DQ pads and the first CA pads.

16. The semiconductor package according to claim 15, wherein the plurality of second power/ground pads is directly and electrically connected to a plurality of second gold fingers on the first surface of the carrier substrate through a plurality of fifth bond wires.

17. The semiconductor package according to claim 16 further comprising:
a molding compound encapsulating the first electronic component, the second electronic component, the plurality of first bond wires, the plurality of second bond wires, the plurality of third bond wires, the plurality of fourth bond wires, and the plurality of fifth bond wires.

18. The semiconductor package according to claim 11 further comprising:
a plurality of connecting elements on the second surface of the carrier substrate.

19. The semiconductor package according to claim 11, wherein the first electronic component is a System on Chip (SoC).

20. The semiconductor package according to claim 11, wherein the side sector is contiguous with the first sector and the second sector.
